(19) United States
(12) Patent Application Publication
(10) Pub. No.: US 2026/0348050 A1
(43) Pub. Date: Nov. 5, 2026

(54) HETEROEPITAXIAL GROWTH OF SINGLE CRYSTALLINE DIAMOND

(71) Applicant: TECHNISCHE UNIVERSITEIT DELFT, Delft (NL)

(72) Inventor: Ryoichi Ishihara, Rijswijk (NL)

(21) Appl. No.: 19/107,993

(22) PCT Filed: Aug. 29, 2023
(86) PCT No.: PCT/NL2023/050444

§ 371 Date: Feb. 28, 2025

(30) Foreign Application Priority Data
Aug. 29, 2022 (NL) 2032889

(51) Int. Cl. C30B 29/60; C30B 25/04; C30B 25/10; C30B 25/18; C30B 29/04

(52) U.S. Cl. CPC C30B 29/605; C30B 25/04; C30B 25/105; C30B 25/183; C30B 25/186; C30B 29/04

(57) ABSTRACT

A method of forming single crystalline diamond is described wherein the method comprises the steps of forming at least one inorganic dielectric layer over a top surface of a substrate; forming nanoholes, preferably a two-dimensional array of nanoholes, in the at least one insulating layer, the base of each nanohole exposing at part of the top surface of the substrate, the dimensions of the nanoholes being selected between 10 nm and 500 nm; forming single crystalline diamond grains in and at least partly over the nanoholes; and, forming a single crystalline diamond layer over the single crystalline diamond grains.

### CROSS-REFERENCE TO RELATED APPLICATION(S)

This Application is a Section 371 National Stage Application of International Application No. PCT/NL2023/050444, filed Aug. 29, 2023 and published as WO 2024/049294 A1 on Mar. 7, 2024, in English.

### TECHNICAL FIELD

The embodiments relate to heteroepitaxial growth of diamond, and, in particular, though not exclusively, to a method for hetero-epitaxially growing single crystalline diamond, such as single crystalline diamond grains or a single crystalline layer, a structure comprising a crystalline diamond layer and a nanohole template for forming a structure comprising single crystalline diamond such as a single crystalline diamond layer or a diamond substrate.

### BACKGROUND

Diamond single crystal substrates are typically made by high pressure and high temperature diamond (HPHT) growth methods, that mimic the thermodynamic conditions in nature wherein diamond is formed. The maximum size, of approx. 2×2 mm of single crystalline diamond substrate with low impurity level that can be realized by such growth methods is however very small. Because of such small substrate sizes, advance nanofabrication equipment which use wafer sizes of two inch or larger cannot be used. Additionally, the price of such single crystal substrates is very high.

It is possible to grow polycrystalline diamond on a large surface using CVD, however the crystalline size, or the grain size, is very small and hence there are many defects between the grains. Consequently, the properties of such layers are not suitable for high performance applications.

M. Schreck et al in their article Heteroepitaxial growth of diamond using Ir/SrO3 buffer layer on 4-inch silicon substrate, Scientific Reports, describe heteroepitaxial growth of diamond on a four-inch Ir/SrTIO3 substrate. Similarly, Aida et al, in their article Fabrication of freestanding heteroepitaxial diamond structure via micropatterns and microneedles Applied Physics Express 9, 035504 (2016) http://doi.org/10.7567/APEX.9.035504 describe the fabrication of heteroepitaxial diamond substrates via a process of etched diamond micropatterns. However, these films include many defects and impurities and have a high strain. Additionally the growth time (one day or more) of these films is too long.

Hence, from the above, it follows that there is a need in the art for improved methods for epitaxial growth of diamond. In particular, there is a need in the art for methods for epitaxial growth of diamond layers that can be used for realizing wafer-scale single crystalline diamond layers and substrates.

### SUMMARY

In an aspect, the embodiments may relate to a method of forming single crystalline diamond, wherein the method comprises: forming at least one inorganic dielectric layer over a top surface of a substrate; forming nanoholes in the dielectric layer, the base of each nanohole exposing at part of the top surface of the substrate; and, hetero-epitaxially growing single crystalline diamond grains in and at least partly over the nanoholes.

In an embodiment, a chemical vapour deposition technique, preferably a microwave plasma enhanced chemical vapour deposition (MWCVD) technique, may be used to form the single crystalline diamond grains in and over the nanoholes. In an embodiment, the dimensions of the nanoholes may be selected between 10 nm and 800 nm. In another embodiment, the dimensions of the nanoholes may be selected between 10 nm and 500 nm.

The embodiments in this application enable growth of single crystalline diamond thin film layers on a large surface that have reduced defects. Nano-patterns are formed on a large host substrate forming a nano-patterned template for the formation of a single crystalline diamond layer or substrate. The nano-patterned template may be used to form a pattern of single crystal diamond grains of a substrate. A high-quality diamond crystal layer or substrate may be grown out of the regular pattern of single crystal diamond grains because during growth the single crystal diamond grains may connect on the surface to from a continuous epitaxial diamond layer.

In an embodiment, a two-dimensional array of nanoholes may be formed in the inorganic dielectric layer.

In an embodiment, the substrate may comprise an epitaxial base layer wherein the top surface of the epitaxial base layer forms the top surface of the substrate. In an embodiment, the epitaxial base layer may comprise an Iridium layer or a Cu—Ir alloy.

In an embodiment, the method may further comprise: hetero-epitaxially growing a single crystalline diamond layer over the single crystalline diamond grains using a chemical vapour deposition technique wherein the single crystalline diamond layer may have a thickness between 1 and 1000 micrometer, preferably between 1 and 500 micrometer.

Hence, the nanoholes may be used as sites for forming an array of single crystal diamond grains that may form a template for growing a single crystalline diamond layer. When using such template single crystalline diamond grains may be grown such that they connect, coalescent and from a continuous epitaxial diamond layer that covers the surface of the insulating layer.

In some embodiments, after formation of the single-crystalline diamond layer, the substrate including the insulating layer may be removed using well-known etching and/or grinding methods, so that a single-crystalline diamond substrate is formed.

In an embodiment, a microwave plasma enhanced chemical vapour deposition (MWCVD) technique is used for the formation of the single crystalline diamond grains and/or the single crystalline diamond layer.

In an embodiment, before the single crystalline diamond layer is grown over the crystalline diamond grains, the inorganic insulating layer is removed, preferably using a selective etching technique. Hence, in this embodiment, the inorganic insulating layer is removed to form diamond nanopillars on the substrate, wherein the nanopillars on the substrate are used as a template to form a high quality single crystalline diamond layer.

In embodiment, the epitaxial base layer may be in direct contact with the substrate, preferably a MgO substrate, In an embodiment, at least one buffer layer is provided between the epitaxial base layer, preferably the substrate being a Si or a SIC substrate. The buffer layer may be selected to have a thickness selected between 10 nm and 10 micrometer, preferably 20 nm and 5 micrometer, more preferably 40 nm and 2 micrometer.

In an embodiment, the at least one buffer layer may include a an SrTiO₃ layer and/or YSZ layer.

In an embodiment, the inorganic insulating layer comprise an oxide layer, such as SiO₂ or an Al₂O3 layer. In another embodiment, the inorganic insulating layer may comprise a nitride layer, such as a Si₃N4 layer. In yet another embodiment, the inorganic insulating layer may comprise an oxynitride layer.

In an embodiment, the thickness of the inorganic insulating layer may be selected between 10 nm and 10 micron, preferably 20 nm and 5 micron, more preferably 40 micron and 2 micron.

In an embodiment, the nanoholes may form a grid or array of nanoholes over the substrate, wherein the pitch between two neighboring nanoholes may be selected between 20 nm and 1000 nm.

In an embodiment, the cross-sectional shape of the nano-holes may be a rectangular, preferably a square

In an embodiment, the sides of the rectangular nano-holes may be aligned with crystalline orientations of the substrate and/or the epitaxial base layer.

In an embodiment, the horizontal cross-sectional dimensions of the nanoholes have a width selected between 10 nm and 500 nm and/or a depth between 10 nm and 10 micrometer, preferably 20 nm and 5 micrometer, more preferably 50 nm and 1 micrometer.

In an embodiment, the nanoholes may form a two-dimensional grid, wherein the sides of the nanoholes, e.g. square nanohole or triangular nanoholes, are aligned with the crystallographic orientation of the substrate surface.

In an embodiment, the substrate temperature during the growing of the single crystalline diamond grains and/or may be selected between 600 and 900° C. In an embodiment, the microwave power may be selected between 100 W and 2000 W. In an embodiment, the total pressure during growth may be selected between 1 and 50 Torr. In an embodiment, the molar ratio of CH4 and H2 used during the MWCVD may be selected between 0.1% and 10% Applications of the method and the products produces by these methods will be in the semiconductor field including but not limited to high-power electronics used in electric cars, heat spreader for high-power LED used in lighting or for high frequency devices using in 5G base stations.

In an embodiment, during growing the single crystalline diamond grains on the basis of a microwave plasma enhanced chemical vapour deposition, a DC bias is applied to the substrate for enhancement of nucleation of diamond in the nanoholes.

In an embodiment, the voltage applied to the substrate may be selected in the range between −50 V and −500 V.

In a further aspect, the embodiments may relate to a method of forming single crystalline diamond comprising: forming at least one inorganic dielectric layer over a top surface of a substrate; forming nanoholes, preferably a two-dimensional array of nanoholes, in the at least one insulating layer, the base of each nanohole exposing at part of the top surface of the substrate, the dimensions of the nanoholes being selected between 10 nm and 500 nm; forming single crystalline diamond grains in and at least partly over the nanoholes; and, forming a single crystalline diamond layer over the single crystalline diamond grains.

In an embodiment, the one or more single crystalline diamond grains and/or the single crystalline diamond layer are formed using a chemical vapour deposition technique, preferably a microwave plasma enhanced chemical vapour deposition (MWCVD) technique.

In an embodiment, during of the formation of the single crystalline diamond layer, the diamond grains grow over the top substrate such that diamond grains connect and coalescent to form the single crystalline diamond layer.

In an embodiment, the single crystalline diamond layer may have a thickness between 10 nm and 1 mm.

In an embodiment, the substrate may comprises an epitaxial base layer for growing heteroepitaxial diamond formed over a base substrate, wherein the top surface of the epitaxial base layer forms the top surface of the substrate, preferably the epitaxial base layer comprising an layer of Iridium or a layer of an Iridium alloy, such as a Cu—Ir alloy.

In an embodiment, the epitaxial base layer may be in direct contact with the base substrate, preferably the base substrate being a MgO substrate.

In an embodiment, the substrate may further include at least one buffer layer between the epitaxial base layer and the base substrate, preferably the base substrate being a Si substrate or a SIC substrate.

In an embodiment, the at least one buffer layer may include an SrTIO3 layer and/or YSZ layer.

In an embodiment, the method may further comprise: forming freestanding diamond nanopillars by removing the inorganic dielectric layer before forming the single crystalline diamond layer over the crystalline diamond grains, preferably the inorganic insulating layer being removed using a selective etching technique.

In an embodiment, after forming the single crystalline diamond layer over the crystalline diamond grains, separating the single crystalline diamond layer and the substrate at the position of the nanopillars.

In an embodiment, the inorganic dielectric layer may comprise an oxide layer, such as an SIO₂ or an Al₂O₃ layer or a nitride layer, such as a Si₃N₄ layer or an oxynitride layer; and/or, the thickness of the inorganic dielectric layer may be selected between 10 nm and 10 micrometer, preferably 20 nm and 5 micrometer, more preferably 40 nm and 2 micrometer.

In an embodiment, the nanoholes may form a grid of nanoholes over the substrate, wherein the pitch between two neighboring nanoholes is selected between 20 nm and 1000 nm.

In an embodiment, the horizontal cross-sectional shape of the nanoholes may be rectangular thereby defining rectangular nanoholes or wherein the horizontal cross-sectional shape of the nanoholes is triangular thereby forming triangular nanoholes.

In an embodiment, the sides of the rectangular or triangular nanoholes may be aligned with the crystalline orientation of the surface of the substrate and/or the epitaxial base layer.

In an embodiment, the nanoholes may be rectangular nanoholes and the surface of the substrate and/or epitaxial base layer has a (100) orientation and the sides of the rectangular nanoholes are parallel to the orientation of the substrate and/or epitaxial base layer.

In an embodiment, the nanoholes may be triangular nanoholes and the surface of the substrate has a (111) orientation and the sides of the triangular nanoholes are parallel to the orientation of the surface of the substrate and/or epitaxial base layer.

In a yet further aspect, the embodiments may relate to a single crystalline diamond structure comprising a substrate, e.g. a wafer-based substrate; an inorganic dielectric layer over the substrate comprising nanoholes, preferably a two-dimensional array of nanoholes; single crystalline diamond grains formed in and at least partly over the nanoholes.

In an embodiment, the single crystalline diamond structure may include a single crystalline diamond layer formed over the single crystalline diamond grains. In an embodiment, the single crystalline diamond thin film layer has a thickness between 10 nm and 1 mm.

In an embodiment, the substrate may comprise an epitaxial base layer formed over a base substrate, the epitaxial base layer being configured for growing heteroepitaxial diamond, wherein the top surface of the epitaxial base layer forms the top surface of the substrate.

In an embodiment, the epitaxial base layer may comprise a layer of Iridium or a layer of an Iridium alloy, such as a Cu—Ir alloy.

In an embodiment, the epitaxial base layer may be in direct contact with the base substrate, preferably the base substrate being a MgO substrate.

In an embodiment, the substrate may further include at least one buffer layer between the epitaxial base layer and the base substrate, preferably the base substrate being a Si substrate or a SIC substrate.

In an embodiment, the at least one buffer layer may include an SrTiO₃ layer and/or YSZ layer.

In an embodiment, the inorganic dielectric layer may comprise an oxide layer, such as an SIO₂ or an Al₂O₃ layer or a nitride layer, such as a Si₃N₄ layer or an oxynitride layer, and/or, the thickness of the inorganic dielectric layer may be selected between 10 nm and 10 micrometer, preferably 20 nm and 5 micrometer, more preferably 40 nm and 2 micrometer.

In an embodiment, the nanoholes may form a grid of nanoholes over the substrate, wherein the pitch between two neighboring nanoholes is selected between 20 nm and 1000 nm.

In an embodiment, the horizontal cross-sectional shape of the nanoholes may be rectangular thereby defining rectangular nanoholes or wherein the horizontal cross-sectional shape of the nanoholes may be triangular thereby forming triangular nanoholes.

In an embodiment, the sides of the rectangular or triangular nanoholes may be aligned with the crystalline orientation of the surface of the substrate and/or the epitaxial base layer.

In an embodiment, nanoholes may be rectangular nanoholes;

In an embodiment, the surface of the substrate and/or epitaxial base layer may have a (100) orientation.

In an embodiment, the sides of the rectangular nanoholes may be oriented parallel to the orientation of the substrate and/or epitaxial base layer.

In an embodiment, the nanoholes may be triangular nanoholes.

In an embodiment, the surface of the substrate may have a (111) orientation and the sides of the triangular nanoholes may be oriented parallel to the orientation of the surface of the substrate and/or epitaxial base layer.

The invention will be further illustrated with reference to the attached drawings, which schematically will show embodiments according to the invention. It will be understood that the invention is not in any way restricted to these specific embodiments.

### BRIEF DESCRIPTION OF THE DRAWINGS

FIGS. 1A and 1B depict a nanostructure template for growing a single crystalline diamond grain according to an embodiment;

FIG. 2 depicts a schematic for realizing an array of single crystalline diamond grains and for growing an epitaxial diamond thin film layer according to an embodiment;

FIG. 3 depicts a top view of a structure for forming an array of single crystalline diamond grains according to an embodiment;

FIG. 4 depicts a nanostructure comprising a single crystalline diamond grain according to an embodiment;

FIGS. 5A and 5B depict top views of a structure for forming an array of single crystalline diamond grains according to an embodiment;

FIG. 6A-6D depicts a method for growing an epitaxial diamond layer according to an embodiment;

FIGS. 7A and 7B depicts a top view of a structure for forming an array of single crystalline diamond grains according to another embodiment of the invention

### DESCRIPTION OF THE EMBODIMENTS

The embodiments in this application aim to solve or at least substantially reduce problems related to the realisation of single crystalline diamond, in particular single crystalline layers and single crystalline substrates. The embodiments aim to solve these problems using nano-patterns, in particular nanoholes, that are formed in an insulating layer formed over substrate which has a crystalline structure that is suitable for hetero-epitaxial growth of single crystalline diamond. For example, the top surface of the substrate may have a substantially matches a crystalline structure of single crystalline diamond. In some embodiment, the nano-patterns may be formed in an insulating (dielectric) layer formed over an epitaxial base layer which has a crystalline structure that substantially matches a crystalline structure of single crystalline diamond. This epitaxial base layer may be formed over a substrate, e.g. a Silicon substrate. These nanoholes may be used as sites for forming an array of single crystalline diamond grains that may form a template for growing a single crystalline diamond layer. In particular, when using such nanoholes template in an embodiment, single crystalline diamond grains may be grown such that they connect, coalescent and from a continuous epitaxial diamond layer that covers the surface of the insulating layer.

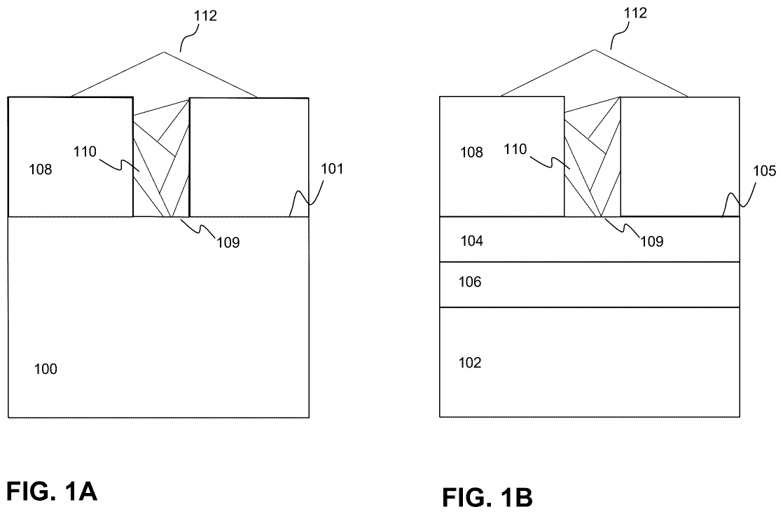

FIGS. 1A and 1B depict cross-sectional schematic of exemplary embodiments of a nano-hole structure for growing a single crystalline diamond grain according to an embodiment. Such structure may be referred to a nano-hole template. As shown in FIG. 1A, the structure may include a substrate 100 having a top surface 101, wherein the crystalline structure is suitable for heteroepitaxial growth of diamond. For example, the crystalline of the substrate may approximately match a crystalline structure of a single crystal diamond. A dielectric layer 108 may be provided over the substrate and a nanohole may be formed in the insulating layer such that the base of the hole exposes part 109 of the top surface of the substrate.

The thickness of the insulating layer may be selected between 10 nm and 10 micrometer so that holes may have a depth between 10 nm and 10 micron. Here the term nanohole refers to holes in the dielectric layer that have dimensions smaller than a micrometer, preferably between 10 nm and 800 nm, more preferably between 10 nm and 500 nm. The horizontal cross-sectional shape of the nanohole may have different geometrical shapes depending on the crystalline orientation of the substrate. For example, in an embodiment, the substrate may have an in-plane (100) orientation. In another embodiment, the substrate may have an in-plane (111) orientation.

As will be described hereunder in greater detail, the substrate comprising the nanoholes may be used as a template for forming a single crystalline heteroepitaxial grown diamond layer. In particular, a heteroepitaxial growth technique such as a plasma-enhanced CVD technique may be used to form crystalline diamond in the nanohole. During the vertical growth, defects will be trapped and single crystalline diamond grains 110 will be filtered out so that a small single crystalline diamond grain 112 may be formed over the nano hole. This way, the nanohole may form a nucleation site for the formation of a single crystalline diamond grain.

In some embodiments, the substrate may have a (multi) layered structure. An example of a nanohole structure comprising a multi-layered substrate is depicted in FIG. 1B, the structure may include base substrate 102, e.g. a silicon substrate, on an which an epitaxial base layer 104 is formed which is suitable for heteroepitaxial growth of diamond. For example, the epitaxial base layer may approximately match the crystalline structure of diamond to form a buffer layer between the base substrate and the diamond. Materials for the epitaxial base layer may include at least one of beta-SIC, MgO, c-BN, Al₂O₃, Ni, Ir, Cu, TiC, Co, Ni₃Si₄, Ni3Ge. In an embodiment the epitaxial base layer may be an iridium Ir layer or an alloy therefore. In an embodiment, a layer of a Cu—Ir alloy may be used. In some embodiments, to form the epitaxial base layer on the silicon base substrate a further buffer layer 104 may be used wherein the buffer layer may have a thickness between 10 and 100 nm. In an embodiment, the buffer layer may include a SrTiO₃ layer and/or YSZ layer 106. Further, an insulating layer 108, e.g. an Al₂O₃ and/or SIO2 layer, may be formed over the epitaxial base wherein nanoholes may be formed in the insulating layer such that the base of the nanohole exposes the epitaxial base layer. Crystalline diamond, in particular single crystalline diamond grains may be formed in the nanohole in a similar way as described with reference to FIG. 1A, wherein during the vertical growth, defects will be trapped and grains 110 will be filtered out so that a small single crystalline diamond 112 may be formed over the nano hole.

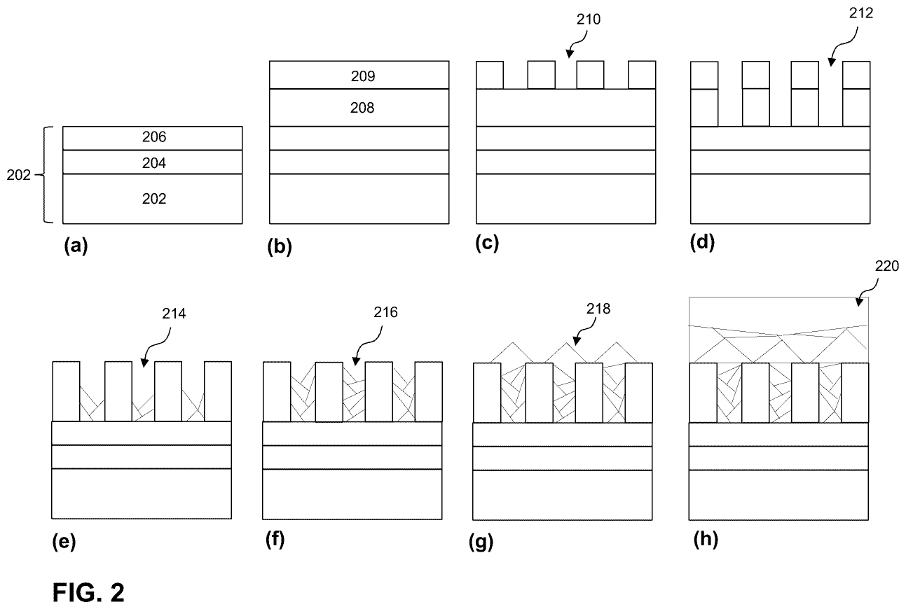

FIG. 2A-2H depicts a method of epitaxial growth of diamond according to an embodiment. In particular, the method may start with a substate 200 (FIG. 2A) which a crystalline structure that approximately matches the crystalline structure of diamond. As already described with reference in some embodiment, the substrate may be a single substrate. In other embodiments, the substrate may be a multi-layered substrate including a base substrate 202 e.g. such as a silicon base substrate, e.g. Si (100) or Si (111) substrate, a silicon carbide β-SIC (100) or B-SIC (111) substrate or a manganese oxide MgO (100) or MgO (111) substrate. In an embodiment, the substrate may be a wafer. An epitaxial base layer 206, which is suitable for heteroepitaxial growth of diamond (e.g. that has a crystalline structure that approximately matches the crystalline structure of diamond) may be formed over the base substrate. In some embodiments, the epitaxial base layer may be deposited directly onto the base substrate. For example, in case of a MgO substrate, an Ir layer may be formed directly onto the substrate to form the epitaxial base layer. Here, sputtering technique at high substrate temperatures 800-900° C.

In further embodiments, before formation of the base layer, a further buffer layer 204 may be deposited on the base substrate, wherein the buffer layer may form a buffer between the base substrate and the epitaxial base layer 206. In an embodiment, the buffer layer may include SrTIO3 layer. In a further embodiment, the buffer layer may include YSZ layer. Such buffer layer may be used in case the crystalline mismatch between the substrate and crystalline Ir layer is too large, e.g. in case of a Si substrate. The buffer layer may be epitaxially grown on the substrate using a suitable deposition method such as MBE or pulsed-laser deposition.

Then in a further step (FIG. 2B) an insulating layer 208, e.g., SiO2 or Al₂O₃, may be deposited on the substrate surface by PECVD, LPCVD or thermal oxidation. The thickness can be in the range of 10 nm-1000 nm with a typical value of 500 nm. A mask layer 209 may be formed over the insulating layer. Then holes 210 may be formed in the mask layer (FIG. 2C). Typically, the holes may have dimensions selected between 10 nm and 800 nm, preferably between 10 nm and 500 nm.

Holes 212 may be etched in the insulating layer (FIG. 2D). The holes may be formed using an anisotropic etch, such as a reactive ion etching (RIE) technique or an another suitable anisotropic etch such as the known Bosch process which is a high-aspect ratio plasma etching process. This etch process includes cyclic isotropic etching and fluorocarbon-based protection film deposition by quick gas switching cycles, wherein the SF₆ plasma cycle etches silicon, and the C₄F₈ plasma cycle creates a protection layer.

The holes may be etched through the insulating layer so that the base (bottom) of the holes expose the epitaxial base layer (or—if no multi-layer substrate is used-the substrate). The pitch between the holes may be selected in the range between 20 nm and 1000 nm. In an embodiment, the cross-sectional shape of the holes may be rectangular, preferably a square, or triangular. In a further embodiment, the edges of the rectangular and/or triangular holes may be aligned with the crystal direction of the substrate and/or the epitaxial base layer.

Then, diamond may be grown hetero-epitaxially in the nanoholes using a deposition technique that is suitable for grown epitaxial diamond, such a chemical vapour deposition technique. In an embodiment, a microwave plasma enhanced chemical vapour deposition (MWCVD) technique may be use. In an embodiment, the diamond may be grown at temperatures selected in a range between 600 and 900° C., preferably around 750° C. Further growth parameters may include CH4 and H2 at a pressure of 10 and 50 mBar and an applied microwave power selected between 100 and 2000 W. During growth, single crystalline diamond grains 214 will nucleate at the surface of the base layer (FIG. 2E) which is exposed at the base of the holes.

This way, during the deposition process, the holes 216 will be filled with diamond grains (FIG. 2F) wherein the holes act as grain filters so that when the diamond exits the holes, a single crystalline grain is formed over the holes. Typically, these single crystalline diamond grains that form over the holes will have a pyramid shape (FIG. 2G) due to preferred growth direction of the crystalline diamond material. During deposition, the total pressure can be in the range of 1-50 Torr. Further, the molar ratio of CH4 and H2 may be selected in the range of 0.1% to 10%.

In an embodiment, the deposition system may have a substrate DC bias for enhancement of nucleation in the initial phase of the growth. In an embodiment, the voltage applied to the substrate may be selected in the range between −50 V and −500 V.

Then, the epitaxial growth of diamond may be continued so that the pyramid shaped diamond grains grow towards each other until the top surface of the pattemed insulating layer is completely covered with a diamond layer. Diamond growth may be continued to form a thin-film single crystalline diamond layer over the substrate. The diamond crystals which exit from those holes will coalesce and become a large surface single crystalline diamond layer. This way, if the holes are made over entire wafer, wafer-sized single-crystalline diamond layers can be formed. In an embodiment, the thickness of the single crystalline layer may be selected between 10 nm and 1 mm. In another the single crystalline layer may be selected between 10 nm and 100 micrometer. In yet another embodiment, the single crystalline layer may be selected between 10 nm and 10 micrometer.

In some embodiment, after formation of the single-crystalline diamond layer, the substrate and the insulating layer may be removed using well-known etching, grinding and/or (mechanical) polishing methods, to form a single-crystalline diamond substrate.

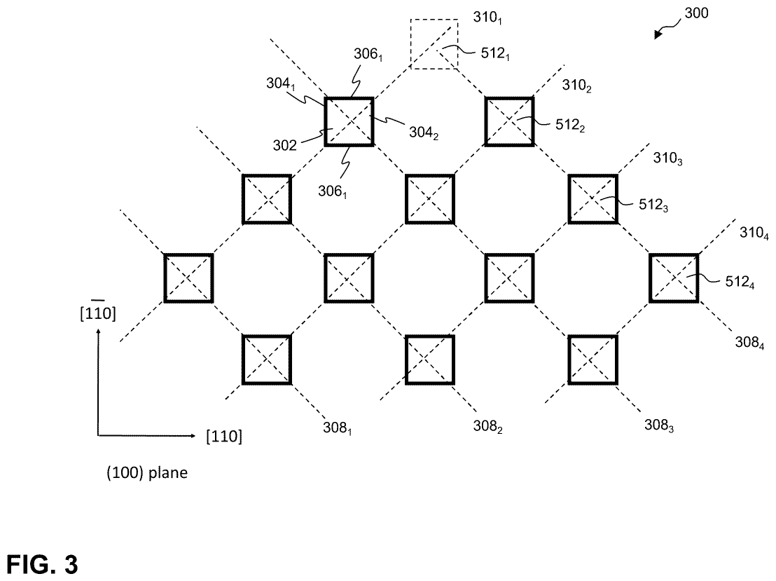

The shape and dimensions of the holes and the arrangement of holes may be varied and optimized for effective removing of defects and coalescence of small crystals. The nanoholes may have a particular shape (e.g. rectangular, triangular, circular, etc.) having an effective dimension (e.g. length, width, base, height, diameter, etc.) selected between 10 nm and 500 nm. An exemplary embodiment is illustrated in FIG. 3, which shows a top view of a silicon substrate 300 with (100) orientation including a layer structure provided over the substrate, wherein the layer structure includes a plurality of nanoholes 302 arranged in a regular grid as described with reference to FIG. 2.

The horizonal (i.e. in plane) cross sectional shape of nanoholes may be square with sides parallel to the crystal directions of <110>. For example, first sides 304_{1,2} of nanohole 302 may be parallel to the [110] direction and second sides 306_{1,2} of the nanohole 302 may be arranged parallel to the [110] direction of the substrate. For this particular shape and orientation an expected shape of a small diamond grain grown out from the holes can be determined. In an embodiment, the rectangular shape of the nanoholes may have dimensions selected between 10 nm and 500 nm (width) and between 10 nm and 500 nm (length).

As for the patterns of array of holes shown in FIG. 3, for a (100) crystalline oriented substrate, in an embodiment, the (centre of) square holes may be arranged on the cross points, e.g. cross points 312₁₋₄, of a diagonal tiling, e.g. a diagonal square tiling pattern, formed by lines 308₁₋₄,310₁₋₄, wherein the sides of the square holes are arranged parallel to the <110> orientation of the substrate as shown in FIG. 3.

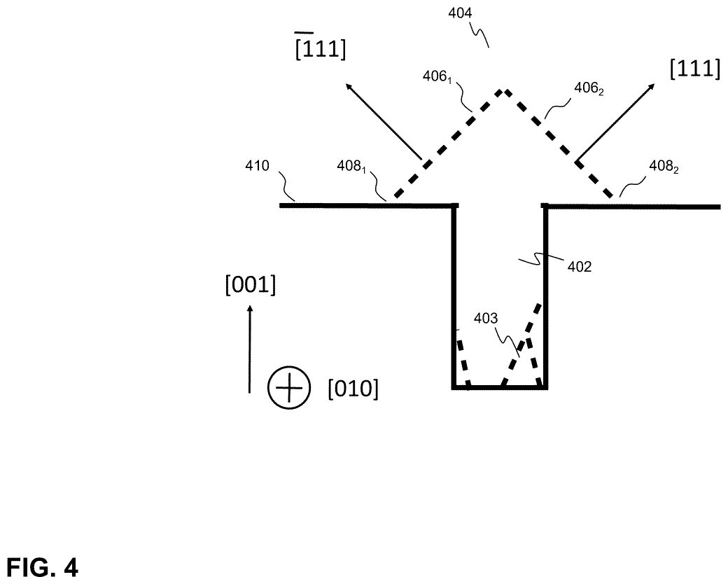

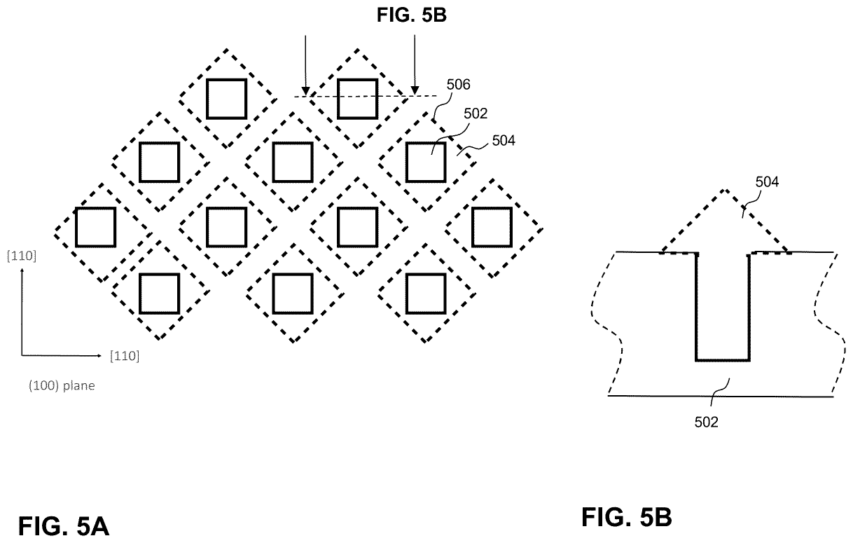

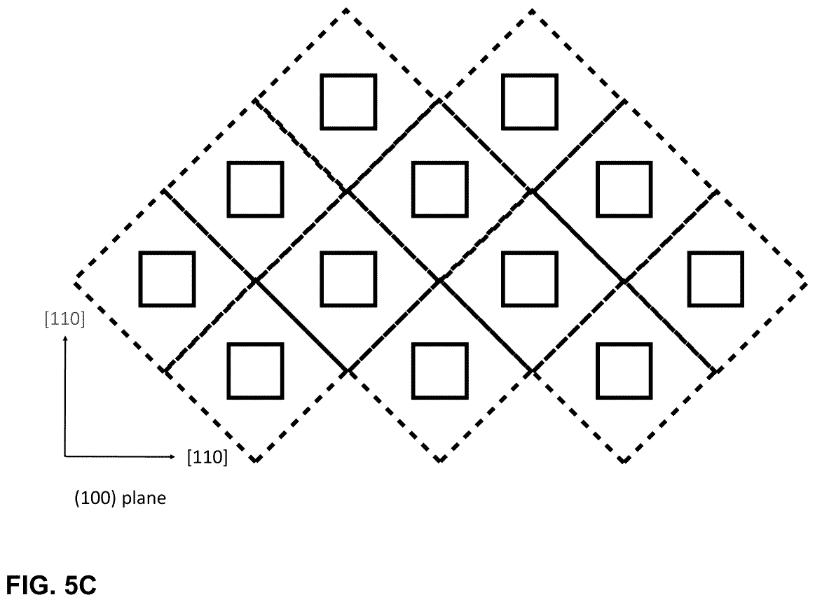

FIG. 4 depicts a cross-sectional view of a nanohole 402 which is used as a seed structure to grow a small single crystalline diamond structure 404. As shown in the figure, the slowest growth speed of the crystalline structure is expected on (111) crystal surfaces 406_{1,2} and the facet will be formed by the corresponding surfaces. The edges 408_{1,2} of the crystal grain with the top surface 410 of the substrate is a straight line parallel to <110> orientations (as is shown in more detail in FIG. 5). The shape and orientation of the hole will thus effectively filter out crystals grains 403 that have other crystallographic orientations.

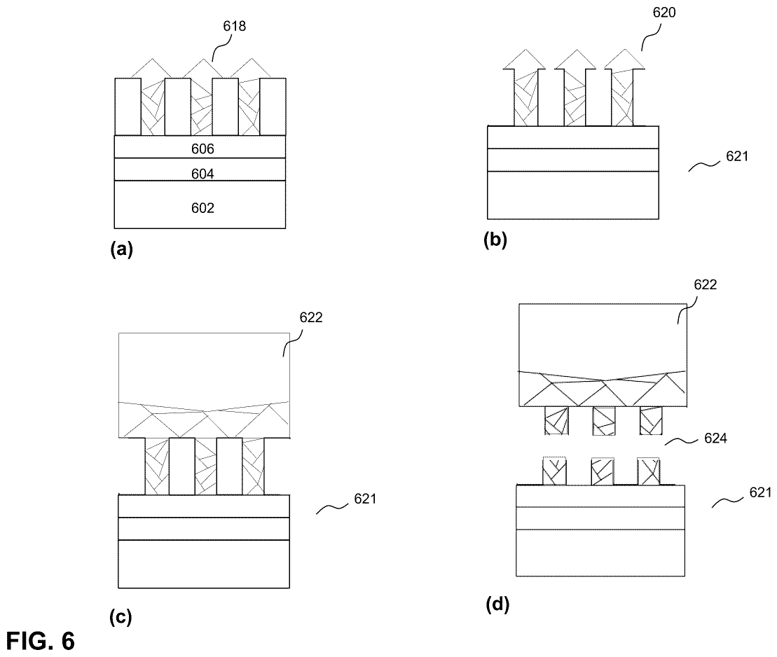

FIG. 5A-5C illustrates the epitaxial growth of the diamond structures using nanostructured template according to an embodiment. In particular, FIG. 5A and SB show horizontal and vertical cross sections respectively of the nanohole template including single crystal diamond structures grown from the nanoholes. Due to the alignment of orientation of the holes with the crystalline orientation of the substrate, effective coalescence of adjacent small crystals 504 grown in holes 502 will occur. The small diamond crystals will have an expected pyramidal shape with edges 506 (denoted by the dashed lines) that are parallel to the <110> crystalline orientation of the substrate. The dashed lines in FIG. 5A show the orientation of the edges of the pyramidal single crystal diamonds that are formed over nanoholes with respect to the crystalline orientation of the substrate at a first time instance during growth. FIG. 5C shows the same array of single crystal diamonds at a later second time instance wherein the diamonds have grown in their preferential crystalline direction so that the edge of the diamonds border each along the <110> orientation. FIG. 6A-6D depict a method of epitaxial growth of diamond according to another embodiment. In this particular example, single crystalline grain diamonds may be formed over nanoholes in a similar way as described with reference to FIG. 2A-2G. As shown in FIG. 6A such structure may include a substrate 602, an epitaxial base layer 606 and, optionally, one or more buffer layers 604 and an insulating layer comprising nanohole wherein single crystal diamond grains are grown out of and over each nanohole. Then, before the single crystalline grain diamonds coalescence into a diamond layer the insulating layer is removed, thereby forming an array of freestanding diamond nanopillars 620 with a single crystalline diamond grain on top (FIG. 6B). This substrate with freestanding diamond nanopillars may be used as a template 621 to grow a diamond layer 622 (FIG. 6C). In an embodiment, the diamond layer may be a bulk diamond layer of 500 microns or thicker (FIG. 6C). Thereafter, the template and the bulk diamond layer may be separated at the height 624 of the nanopillars (FIG. 6D).

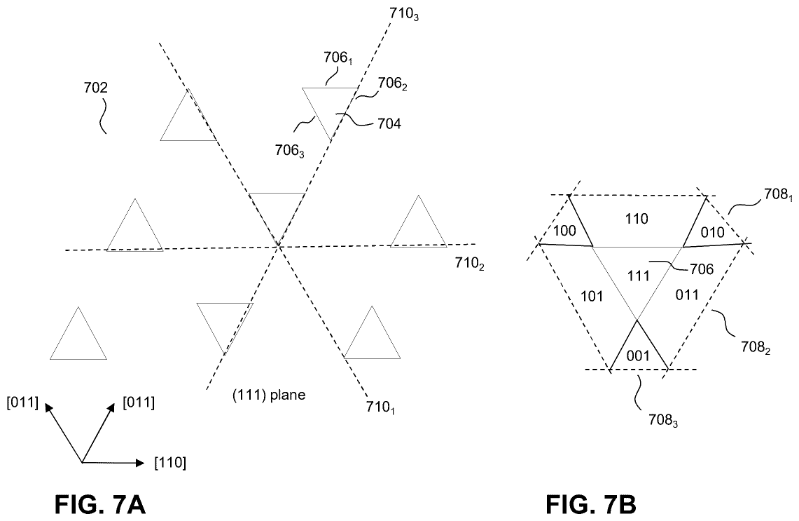

As described above, the shape of the nanoholes are not limited to the shape as described with reference to FIG. 3-5. FIGS. 7A and 7B show another embodiment of a nanostructured template according to an embodiment. In particular, the figure shows of a top view of a silicon substrate 702 that has a surface with an (111) orientation. A layer over the substrate may include a plurality of triangular nanoholes, for example triangles 7041,2, arranged in a regular grid as described with reference to FIG. 7A, wherein the sides of the triangular nanoholes may be arrange parallel to the crystal directions of <110>. The sides of the triangular shape of the nanoholes may have dimensions selected between 10 nm and 500 nm.

For example, first side 7061 of nanohole 7041 may be parallel to a first direction, second side 7061 of the nanohole 7041 may be arranged parallel to a second direction [011] and third side 7063 of the nanohole 7041 may be arranged parallel to the third direction [011] of the substrate. For this particular shape and orientation, an expected shape of a small diamond grain grown out from the holes can be determined. FIG. 7B illustrates such grain including a (111) triangular (flat) top surface, three (slanted) side surfaces (101)(011)(110) bordering the sides of the triangular top surface and three (slanted) side surfaces (001)(010)(100) arranged at the corners of the triangular top surface. Similar to the patterns of array of holes shown in FIG. 7, for a (111) oriented substrate, in an embodiment, the edges of the triangular holes may be arranged along the orientations of the (111) plane as shown by lines 710₁₋₃.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1. A method of forming single crystalline diamond comprising:
forming at least one inorganic dielectric layer over a top surface of a substrate; the substrate comprises Iridium or an Iridium alloy epitaxial base layer for growing heteroepitaxial diamond formed over base substrate, a top
surface of the epitaxial base layer forming the top surface of the substrate;
forming nanoholes in the at least one inorganic dielectric layer, a base of each nanohole exposing at least part of the top surface of the substrate, dimensions of the nanoholes being selected between 10 nm and 500 nm;
forming single crystalline diamond grains in and at least partly over the nanoholes; and, forming a single crystalline diamond layer over the single crystalline diamond grains.

2. The method according to claim 1 wherein the one or more single crystalline diamond grains and/or the single crystalline diamond layer are formed using a chemical vapor deposition technique or wherein during of the forming of the single crystalline diamond layer, the diamond grains grow over the top surface of the substrate such that diamond grains connect and coalescent to form the single crystalline diamond layer.

3. (canceled)

4. The method according to claim 1 wherein the single crystalline diamond layer has a thickness between 10 nm and 1 mm.

5. The method according to claim 4 wherein the epitaxial base layer is in direct contact with the base substrate or wherein the substrate further includes at least one buffer layer between the epitaxial base layer and the base substrate.

6. (canceled)

7. The method according to claim 5, wherein the at least one buffer layer includes an SrTiO3 layer and/or YSZ layer.

8. The method according to claim 1 wherein the method further comprises:
forming freestanding diamond nanopillars by removing the inorganic dielectric layer before forming the single crystalline diamond layer over the single crystalline diamond grains.

9. The method according to claim 1 wherein the inorganic dielectric layer comprises an oxide layer, such as an SiO2 or an Al2O3 layer or a nitride layer, such as a Si3N4 layer or an oxynitride layer; and/or, wherein thickness of the inorganic dielectric layer is selected between 10 nm and 10 micrometer.

10. The method according to claim 1, wherein the nanoholes form a grid of nanoholes over the substrate, wherein the-a pitch between two neighboring nanoholes is selected between 20 nm and 1000 nm or wherein a horizontal cross-sectional shape of the nanoholes is rectangular thereby defining rectangular nanoholes or wherein the horizontal cross-sectional shape of the nanoholes is triangular thereby forming triangular nanoholes.

11. (canceled)

12. The method according to claim 10 wherein sides of the rectangular or triangular nanoholes are aligned with the a crystalline orientation of the substrate and/or the epitaxial base layer.

13. The method according to claim 1 wherein the nanoholes are rectangular nanoholes and the surface of the substrate and/or epitaxial base layer has a (100) orientation and sides of the rectangular nanoholes are parallel to the orientation of the substrate and/or epitaxial base layer or wherein the nanoholes are triangular nanoholes and the substrate has a (111) orientation and sides of the triangular nanoholes are parallel to the orientation of the substrate and/or epitaxial base layer.

14. (canceled)

15. The method according to claim -wherein the horizontal cross-sectional dimensions of the nanoholes are selected between 10 nm and 500 nm and/or wherein the a depth of the nanoholes are selected between 10 nm and 10 micrometer,

16. The method according to claim 1 wherein substrate temperature during the growing is between 600 and 900-0° C., the-a microwave power is selected between 100 W and 2000 W, the-a total pressure is between 1 and 50 Torr and/or the-a molar ratio of CH4 and H2 between 0.1% and 10%.

17. (canceled)

18. A structure comprising single crystalline diamond comprising
a substrate; wherein the substrate comprises an Iridium or an Iridium alloy epitaxial base layer formed over a base substrate, the epitaxial base layer being configured for growing heteroepitaxial diamond, wherein the a top surface of the epitaxial base layer forms the-a top surface of the substrate;
an inorganic dielectric layer over the substrate, the inorganic dielectric layer comprising nanoholes, pre dimensions of the nanoholes being selected between 10 nm and 500 nm;
single crystalline diamond grains formed in and at least partly over the nanoholes; and
a single crystalline diamond layer formed over the single crystalline diamond grains.

19. The structure according to claim 18 wherein the single crystalline diamond thin layer has a thickness between 10 nm and 1 mm.

20. The structure according to claim 18, wherein the epitaxial base layer is in direct contact with the base substrate or wherein the substrate further includes at least one buffer layer between the epitaxial base layer and the base substrate.

21. (canceled)

22. The structure according to claim 20, wherein the at least one buffer layer includes an SrTiO3 layer and/or YSZ layer.

23. The structure according to claim 18 wherein the inorganic dielectric layer comprises an oxide layer, such as an SiO2 or an Al2O3 layer or a nitride layer, such as a Si3N4 layer or an oxynitride layer; and/or, a thickness of the inorganic dielectric layer is selected between 10 nm and 10 micrometer.

24. The structure according to claim 18 wherein the nanoholes form a grid of nanoholes over the substrate, wherein a pitch between two neighboring nanoholes is selected between 20 nm and 1000 nm; or, wherein a horizontal cross-sectional shape of the nanoholes is rectangular thereby defining rectangular nanoholes or wherein the horizontal cross-sectional shape of the nanoholes is triangular thereby forming triangular nanoholes.

25. (canceled)

26. The structure according to claim 25 wherein the sides of the rectangular or triangular nanoholes are aligned with the a crystalline orientation of the substrate and/or the epitaxial base layer.

27. The structure according to claim 18 wherein the nanoholes are rectangular nanoholes and the substrate and/or epitaxial base layer has a (100) orientation and the-sides of the rectangular nanoholes are parallel to the orientation of the substrate and/or epitaxial base layer or wherein the nanoholes are triangular nanoholes and the substrate has a (111) orientation and sides of the triangular nanoholes are parallel to the orientation the substrate and/or epitaxial base layer,

28. (canceled)
